(19) United States
(12) Patent Application Publication
(10) Pub. No.: US 2024/0395920 A1
(43) Pub. Date: Nov. 28, 2024

(54) HIGH ELECTRON MOBILITY TRANSISTOR AND ITS MANUFACTURING METHOD

(71) Applicant: Silergy Semiconductor Technology (Hangzhou) LTD, Hangzhou (CN)

(72) Inventors: Li Zhang, Hangzhou (CN); Qiukai Huang, Hangzhou (CN); Chen Zhao, Hangzhou (CN); Wenjie Wu, Hangzhou (CN)

(21) Appl. No.: 18/663,404

(22) Filed: May 14, 2024

(30) Foreign Application Priority Data
May 23, 2023 (CN) 202310599220.X

(51) Int. Cl. H01L 29/778; H01L 29/10; H01L 29/66

(52) U.S. Cl. CPC H01L 29/7786; H01L 29/1083; H01L 29/66462

(57) ABSTRACT

A high electron mobility transistor can include: a substrate; a channel layer located above the substrate; a potential energy barrier layer located on the channel layer; a drain electrode and a source electrode configured to at least extend downward to an upper surface of the potential energy barrier layer; a gate conductor located above the potential energy barrier layer; and a current limiting structure located on the potential energy barrier layer and extending upward along the surface of a first side of the source electrode to reduce the saturation current of the transistor, where the first side of the source electrode is a side near the gate conductor.

### RELATED APPLICATIONS

This application claims the benefit of Chinese Patent Application No. 202310599220.X, filed on May 23, 2023, which is incorporated herein by reference in its entirety.

### FIELD OF THE INVENTION

The present invention generally relates to the field of semiconductor technology, and more particular to high electron mobility transistors and associated manufacturing methods.

### BACKGROUND

Group III nitride (III-N) compound semiconductor materials (e.g., GaN) have the characteristics of wide bandgap, high breakdown electric field, and high thermal conductivity. In addition, typical wide band gap heterostructure systems (e.g., containing AlGaN/GaN heterostructures) can generate two-dimensional electron gas (2DEG) channels with high charge concentration and high electron mobility through spontaneous and piezoelectric polarization effect enhancement. A very high current can be allowed to flow between drain and source of a high electron mobility transistor, and the very high current can cause the transistor to self-destruct, possibly within hundreds of nanoseconds.

### BRIEF DESCRIPTION OF THE DRAWINGS

FIG. 1 is a cross-sectional view of an example high electron mobility transistor, in accordance with embodiments of the present invention.

FIG. 2 is a top view of a first example high electron mobility transistor, in accordance with embodiments of the present invention.

FIG. 3 is a top view of a second example high electron mobility transistor, in accordance with embodiments of the present invention.

FIGS. 4A-4D are cross-sectional views of steps of an example manufacturing method of the high electron mobility transistor, in accordance with embodiments of the present invention.

### DETAILED DESCRIPTION

Reference may now be made in detail to particular embodiments of the invention, examples of which are illustrated in the accompanying drawings. While the invention may be described in conjunction with the preferred embodiments, it may be understood that they are not intended to limit the invention to these embodiments. On the contrary, the invention is intended to cover alternatives, modifications and equivalents that may be included within the spirit and scope of the invention as defined by the appended claims. Furthermore, in the following detailed description of the present invention, numerous specific details are set forth in order to provide a thorough understanding of the present invention. However, it may be readily apparent to one skilled in the art that the present invention may be practiced without these specific details. In other instances, well-known methods, procedures, processes, components, structures, and circuits have not been described in detail so as not to unnecessarily obscure aspects of the present invention.

Semiconductor devices are generally manufactured using two complex manufacturing processes: front-end manufacturing and back-end manufacturing. Front-end manufacturing may involve the formation of a plurality of die on the surface of a semiconductor wafer. Each die on the wafer may contain active and passive electrical components, which are electrically connected to form functional electrical circuits. Active electrical components, such as transistors and diodes, have the ability to control the flow of electrical current. Passive electrical components, such as capacitors, inductors, resistors, and transformers, create a relationship between voltage and current necessary to perform electrical circuit functions.

Passive and active components can be formed over the surface of the semiconductor wafer by a series of process steps including doping, deposition, photolithography, etching, and planarization. Doping introduces impurities into the semiconductor material by techniques such as ion implantation or thermal diffusion. The doping process modifies the electrical conductivity of semiconductor material in active devices, transforming the semiconductor material into an insulator, conductor, or dynamically changing the semiconductor material conductivity in response to an electric field or base current. Transistors contain regions of varying types and degrees of doping arranged as necessary to enable the transistor to promote or restrict the flow of electrical current upon the application of the electric field or base current.

Active and passive components are formed by layers of materials with different electrical properties. The layers can be formed by a variety of deposition techniques determined in part by the type of material being deposited. For example, thin film deposition may involve chemical vapor deposition (CVD), physical vapor deposition (PVD), electrolytic plating, and electroless plating processes. Each layer is generally patterned to form portions of active components, passive components, or electrical connections between components.

The layers can be patterned using photolithography, which involves the deposition of light sensitive material, e.g., photoresist, over the layer to be patterned. A pattern is transferred from a photomask to the photoresist using light. The portion of the photoresist pattern subjected to light is removed using a solvent, exposing portions of the underlying layer to be patterned. The remainder of the photoresist may be removed, leaving behind a patterned layer. Alternatively, some types of materials can be patterned by directly depositing the material into the areas or voids formed by a previous deposition/etch process using techniques such as electroless and electrolytic plating.

Depositing a thin film of material over an existing pattern can exaggerate the underlying pattern and create a non-uniformly flat surface. A uniformly flat surface may be used to produce smaller and more densely packed active and passive components. Planarization can be used to remove material from the surface of the wafer and produce a uniformly flat surface. Planarization can involve polishing the surface of the wafer with a polishing pad. An abrasive material and corrosive chemical are added to the surface of the wafer during polishing. The combined mechanical action of the abrasive and corrosive action of the chemical removes any irregular topography, resulting in a uniformly flat surface.

Back-end manufacturing refers to cutting or singulating the finished wafer into the individual die and then packaging the die for structural support and environmental isolation. To singulate the die, the wafer is scored and broken along non-functional regions of the wafer called saw streets or scribes. The wafer may be singulated using a laser cutting tool or saw blade. After singulation, the individual die are mounted to a package substrate that can include pins or contact pads for interconnection with other system components. Contact pads formed over the semiconductor die can then be connected to contact pads within the package. The electrical connections can be made with solder bumps, stud bumps, conductive paste, or wire bonds, as a few examples. An encapsulant or other molding material may be deposited over the package to provide physical support and electrical isolation. The finished package can then be inserted into an electrical system and the functionality of the semiconductor device is made available to the other system components.

The manufacturing process of semiconductor integrated circuits mainly can include the formation of devices such as transistors in the active region of the surface of the semiconductor substrate. These devices need to be isolated from each other through isolation structures. Both trench isolation structure and field oxide isolation structure are often used to isolate the active region of semiconductor substrate.

In particular embodiments, a protective device may be utilized to limit the saturation current of the channel. A high electron mobility transistor in particular embodiments can include: a substrate; a channel layer located above the substrate; a potential energy barrier layer located on the channel layer; a drain electrode and a source electrode configured to at least extend downward to an upper surface of the potential energy barrier layer; a gate conductor located above the potential energy barrier layer; and a current limiting structure located on the potential energy barrier layer and extending upward along the surface of a first side of the source electrode to reduce the saturation current of the transistor, where the first side of the source electrode is a side near the gate conductor.

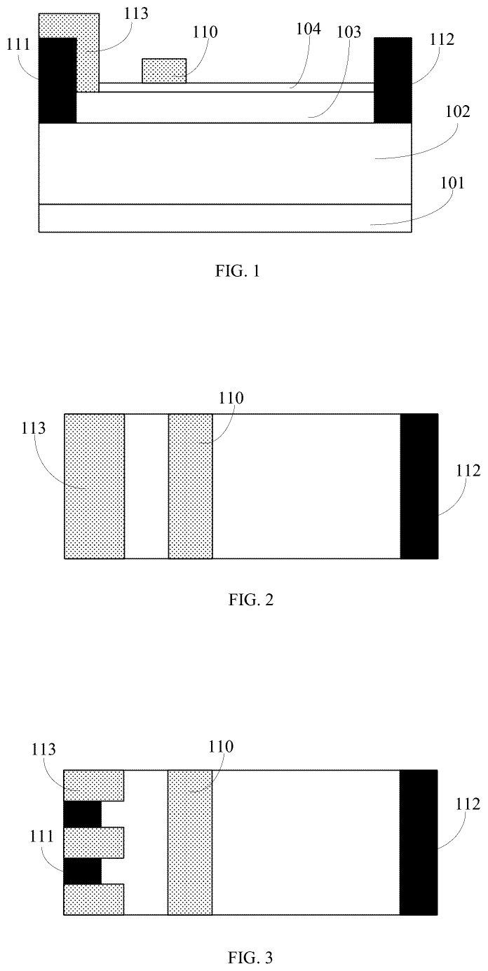

Referring now to FIG. 1, shown a cross-sectional view of an example high electron mobility transistor, in accordance with embodiments of the present invention. Here, the plane of the cross-section is transverse to the plane of substrate 101. The lateral direction in the semiconductor structure of the transistor to be described and the main direction of current flow are horizontal in the example of FIG. 1. In this example, the high electron mobility transistor structure shown in FIG. 1 is based on substrate 101 (e.g., a silicon substrate). A relatively small bandgap layer 102 (e.g., a GaN semiconductor layer) and another relatively large bandgap layer 103 (e.g., an AlGaN semiconductor layer, AlN semiconductor layer, etc.) can be provided on substrate 101 to form a semiconductor heterostructure. The two-dimensional electron gas may be formed at the interface between these two layers, which can form a high electron mobility layer of the channels of the transistor.

In this embodiment, the relatively small bandgap layer can be channel layer 102 of the transistor, and the relatively large bandgap layer can be potential energy barrier layer 103 of the transistor. The two-dimensional electron gas can be located within the top of channel layer 102. In other examples, a buffer layer for improving the lattice matching between the transistor structure and the substrate can be included on substrate 101. The buffer layer can be located between substrate 101 and channel layer 102. The buffer layer can also include a nucleation layer AlN, and the buffer layer may be selected from III-V compound materials (e.g., GaN and AlGaN). A cap layer may also be included on potential energy barrier layer 103, and the cap layer can be selected from III-V compound materials (e.g., GaN, AlGaN, etc.).

Patterned dielectric layer 104 can be located on potential energy barrier layer 103 and can include electrode contact windows. The transistor may also include drain electrode 112, source electrode 111, and gate conductor 110. Source electrode 111 and drain electrode 112 can be located in the electrode contact windows. Also, gate conductor 110 may be located on dielectric layer 104 between source electrode 111 and drain electrode 112. Alternatively, gate conductor 110 can be directly located on potential energy barrier layer 103. In this example, source electrode 111 and drain electrode 112 may extend through dielectric layer 104 and potential energy barrier layer 103 to an upper surface of channel layer 102. In other examples, source electrode 111 and drain electrode 112 may also extend to the interior of potential energy barrier layer 104. In yet another example, source electrode 111 and drain electrode 112 may be located on an upper surface of potential energy barrier layer 103. The materials of the source electrode and the drain electrode may both be metal materials.

Current limiting structure 113 located on the potential energy barrier layer may extend upward along the surface of a first side of source electrode 111, in order to reduce saturation current, where the first side of source electrode 111 is a side near gate conductor 110. For example, current limiting structure 113 may extend from the potential energy barrier layer to an upper surface of the source electrode along the surface of the first side of the source electrode, and can at least cover a portion of the upper surface of the source electrode. A pinch-off voltage below current limiting structure 113 can be lower than a pinch-off voltage of the channel below gate conductor 110 to limit the saturation current of the device. In this example, current limiting structure 113 may be located on the upper surface of potential energy barrier layer 103. In other examples, current limiting structure 113 may extend to the interior of potential energy barrier layer 103, which can better limit the saturation current. The current limiting structure can be made of the same material as the gate conductor and is made of metal materials (e.g., Ti metal, Ni metal, TiN metal, etc.). Of course, the material of the current limiting structure and the material of the gate conductor may also be different.

Due to the pinch-off voltage below current limiting structure 113 being lower than the pinch-off voltage of the channel below gate conductor 110, the introduced current limiting structure 113 can pinch off the carriers earlier than the gate conductor 110 under high drain current, in order to limit the saturation current of the device; that is, may reduce the saturation current of the device, and thereby alleviate device damage caused by hot carriers. The deeper current limiting structure 113 may extend toward the interior of potential barrier layer 103, and the smaller the pinch-off voltage below current limiting structure 113, the better limit of the saturation current of the device. However, as current limiting structure 113 extends deeper into the interior of potential energy barrier layer 103, the on-resistance of device can also increase. Therefore, the position of current limiting structure 113 in potential energy barrier layer 103 can be set according to particular device requirements. In addition, because current limiting structure 113 is next to source electrode 111, the distance between gate electrode and source electrode of the device may not be increased, and the influence on the on-resistance of the device can be relatively small.

Referring now to FIG. 2, shown is a top view of a first example high electron mobility transistor, in accordance with embodiments of the present invention. In this particular example, current limiting structure 113 may fully cover the upper surface of the source electrode.

Referring now to FIG. 3, shown is a top view of a second example high electron mobility transistor, in accordance with embodiments of the present invention. In this particular example, current limiting structures 113 can include a plurality of parts arranged on source electrode 111 in parallel and at intervals along the first direction, where the first direction is perpendicular to the stacking direction of the transistor and the channel extension direction of the transistor. The setting of the current limiting structure in this example can also reduce the influence of the current limiting structure on the on-resistance of the device.

In particular embodiments, the high electron mobility transistor can include a current limiting structure arranged between the gate conductor and the source electrode. Also, the current limiting structure can be close to the source electrode, and pinch-off voltage below the current limiting structure can be smaller than the pinch-off voltage of the channel below the gate conductor. As such, the saturation current of the device can be limited and the increase of the on-resistance of the device can be reduced to the greatest extent.

A manufacturing method for a high electron mobility transistor of particular embodiments can include: forming a source electrode and a drain electrode on a potential energy barrier layer; and forming a gate conductor and a current limiting structure on the potential energy barrier layer, whereby the current limiting structure can extend upward along the surface of a first side of the source electrode to reduce the saturation current of the transistor, and where the first side of the source electrode is a side near the gate conductor.

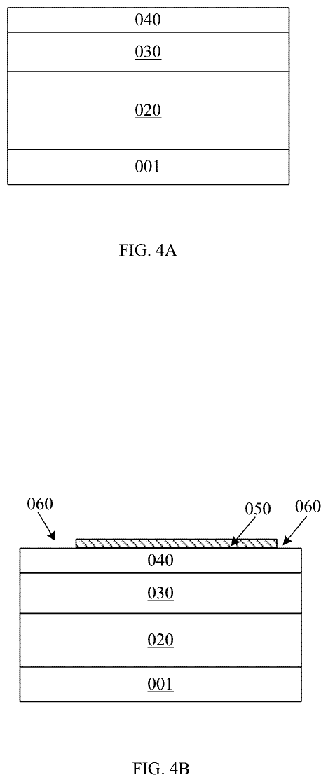

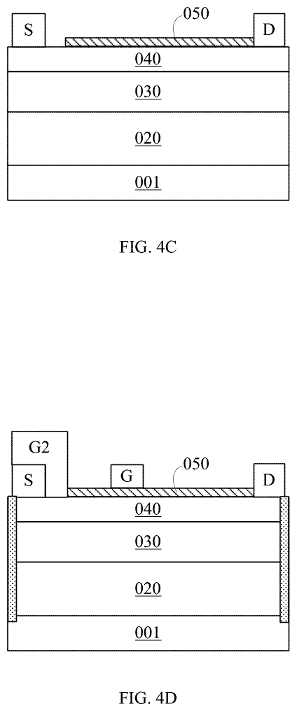

Referring now to FIGS. 4A-4D, shown are cross-sectional views of steps of an example manufacturing method of the high electron mobility transistor, in accordance with embodiments of the present invention. In FIG. 4A, substrate 001 (e.g., a Si substrate) can be provided. Buffer layer 020 may be formed on substrate 001, in order to improve the lattice matching between transistor structure and substrate. Buffer layer 020 can also include a nucleation layer (e.g., AlN material), and buffer layer 020 can be III-V semiconductor materials (e.g., GaN and AlGaN). Channel layer 030 (e.g., GaN semiconductor layer) can be formed on buffer layer 020, and potential energy barrier layer 040 (e.g., AlGaN layer) may be formed on channel layer 030. In other examples, a cap layer can be formed on potential energy barrier layer 040, in order to prevent oxidation of potential energy barrier layer 040. Also, the cap layer may be III-V compound materials (e.g., GaN, AlGaN, etc.).

As shown in FIG. 4B, patterned dielectric layer 050 may be formed on potential energy barrier layer 040, and patterned dielectric layer 050 can include electrode contact windows 060. The forming of patterned dielectric layer 050 may include forming a dielectric layer on potential energy barrier layer 040, forming a photoresist layer on the dielectric layer, using an exposure and development process to form a patterned photoresist layer, using the patterned photoresist layer as a mask, and etching the dielectric layer to form patterned dielectric layer 050.

As shown in FIG. 4C, source electrode S and drain electrode D can be formed at electrode contact windows 060. Source electrode S and drain electrode D can be located on an upper surface of potential energy barrier layer 040, and may respectively be located on both sides of patterned dielectric layer 050. In other examples, source electrode S and drain electrode D may extend to the interior of potential energy barrier layer 040. In yet another example, source electrode S and drain electrode D may extend through potential energy barrier layer 040 to a upper surface of channel layer 030. For example, the materials of the source electrode and drain electrode can both be metal materials.

As shown in FIG. 4D, current limiting structure G2 may be formed on potential energy barrier layer 040, and gate conductor G can be formed on dielectric layer 050 simultaneously. For example, current limiting structure G2 can be formed at a position adjacent to source electrode S, and current limiting structure G2 may extend upward along the surface of a first side of the source electrode to reduce the saturation current of the transistor, where the first side of the source electrode is a side near the gate conductor. Current limiting structure G2 may extend from potential energy barrier layer 040 to the upper surface of source electrode S along the surface of first side of source electrode S, and at least partially cover an upper surface of source electrode S. In one example, current limiting structure G2 may fully cover the upper surface of source electrode S. In another example, current limiting structure G2 can include a plurality of parts arranged on the source electrode in parallel and at intervals along the first direction, where the first direction is perpendicular to the stacking direction of the transistor and the channel extension direction of the transistor.

In particular embodiments, current limiting structure G2 can be located on the upper surface of the potential energy barrier layer, and in other examples, current limiting structure G2 can extend to the interior of potential energy barrier layer 040. For example, the material of current limiting structure G2 and the material of gate conductor G can be metal materials (e.g., Ti metal, Ni metal, TiN metal, etc.). The material of current limiting structure G2 and the material of gate conductor G can be the same or different in certain embodiments.

Prior to forming current limiting structure G2 and gate conductor G, and after forming the drain electrode and the source electrode, the method can also include forming an isolation structure at both sides of the device, such as at the edge position of the device, in order to isolate from other device structures. The isolation structure can be used for trench isolation and/or implantation isolation.

In particular embodiments, the manufacturing method of the high electron mobility transistor can include forming a current limiting structure between the gate electrode and source electrode. The current limiting structure and the gate conductor can be formed simultaneously, and the device including this current limiting structure may be formed without adding any additional process steps.

The embodiments were chosen and described in order to best explain the principles of the invention and its practical applications, to thereby enable others skilled in the art to best utilize the invention and various embodiments with modifications as are suited to particular use(s) contemplated. It is intended that the scope of the invention be defined by the claims appended hereto and their equivalents.

What is claimed is:

1. A high electron mobility transistor, comprising:
a) a substrate;
b) a channel layer located above the substrate;
c) a potential energy barrier layer located on the channel layer;
d) a drain electrode and a source electrode, configured to at least extend downward to an upper surface of the potential energy barrier layer;
e) a gate conductor located above the potential energy barrier layer; and
f) a current limiting structure configured to locate on the potential energy barrier layer and extend upward along the surface of a first side of the source electrode to reduce the saturation current of the transistor, wherein the first side of the source electrode is a side near the gate conductor.

2. The high electron mobility transistor of claim 1, wherein the current limiting structure extends from the potential energy barrier layer to an upper surface of the source electrode along the surface of the first side of the source electrode, and covers at least a portion of the upper surface of the source electrode.

3. The high electron mobility transistor of claim 1, wherein the current limiting structure extends to the interior of the potential energy barrier layer.

4. The high electron mobility transistor of claim 1, wherein the current limiting structure is located on an upper surface of the potential energy barrier layer.

5. The high electron mobility transistor of claim 2, wherein the current limiting structure fully covers the upper surface of the source electrode.

6. The high electron mobility transistor of claim 2, wherein the current limiting structure comprises a plurality of parts arranged in parallel and at intervals along a first direction, wherein the first direction is perpendicular to the stacking direction of the transistor and the channel extension direction of the transistor.

7. The high electron mobility transistor of claim 1, wherein a material of the current limiting structure and the material of the gate conductor is the same.

8. The high electron mobility transistor of claim 1, further comprising a cap layer located on the potential energy barrier layer.

9. The high electron mobility transistor of claim 1, further comprising a dielectric layer located between the potential energy barrier layer and the gate conductor.

10. The high electron mobility transistor of claim 1, further comprising a buffer layer located between the substrate and the channel layer.

11. The high electron mobility transistor of claim 1, wherein a pinch-off voltage below the current limiting structure is lower than a pinch-off voltage of the channel below the gate conductor.

12. A method of forming a high electron mobility transistor, the method comprising:
a) forming a source electrode and a drain electrode on a potential energy barrier layer; and
b) simultaneously forming a gate conductor and a current limiting structure on the potential energy barrier layer,
c) wherein the current limiting structure extends upward along the surface of a first side of the source electrode to reduce the saturation current of the transistor, and wherein the first side of the source electrode is a side near the gate conductor.

13. The method of claim 12, wherein the current limiting structure extends from the potential energy barrier layer to an upper surface of the source electrode along the side surface of one side of the source electrode, and covers at least a portion of the upper surface of the source electrode.

14. The method of claim 12, wherein the current limiting structure extends to the interior of the potential energy barrier layer.

15. The method of claim 12, wherein the current limiting structure is located on an upper surface of the potential energy barrier layer.

16. The method of claim 13, wherein the current limiting structure fully covers the upper surface of the source electrode.

17. The method of claim 13, wherein the current limiting structure comprises a plurality of parts arranged in parallel and at intervals along a first direction, wherein the first direction is perpendicular to the stacking direction of the transistor and the channel extension direction of the transistor.

18. The method of claim 12, wherein a material of the current limiting structure and the material of the gate conductor is the same.

19. The method of claim 12, further comprising:
a) forming a buffer layer on a substrate;
b) forming a channel layer on the buffer layer; and
c) forming the potential energy barrier layer on the channel layer.

20. The method of claim 12, further comprising forming a dielectric layer between the potential energy barrier layer and the gate conductor.
